(19) United States
(12) Patent Application Publication
(10) Pub. No.: US 2026/0305231 A1
(43) Pub. Date: Oct. 1, 2026

(54) SYSTEM AND METHOD OF OFFSET INSPECTION

(71) Applicant: Gudeng Precision Industrial Co., LTD., New Taipei City (TW)

(72) Inventors: Ming-Chien Chiu, New Taipei City (TW); Yung-Chin Pan, New Taipei City (TW); Po-Ting Lee, New Taipei City (TW); Chia-Ho Chuang, New Taipei City (TW)

(21) Appl. No.: 19/426,375

(22) Filed: Dec. 19, 2025

Related U.S. Application Data
(60) Provisional application No. 63/778,610, filed on Mar. 27, 2025.

(51) Int. Cl. H10P 72/00; H10P 72/10

(52) U.S. Cl. CPC H10P 72/0606; H10P 72/1921; H10P 72/1922

(57) ABSTRACT

An air curtain device includes a first chamber, a second chamber, a third chamber, and a diffusion member. The first chamber is in fluid communication with a gas source and receives a gas. The second chamber is in fluid communication with the first chamber, and the third chamber is in fluid communication with the second chamber. The diffusion member is disposed between the second chamber and the third chamber and uniformly supplies the gas from the second chamber to the third chamber. The third chamber includes an internal flow channel having a first end and a second end. The first end is in fluid communication with the second chamber via the diffusion member. The second end is defined by an upright wall and an inclined wall. The air curtain device is configured to provide the gas toward a substrate carrier at an inclined angle through the second end.

### RELATED APPLICATIONS

This application claims priority to U.S. Provisional Patent Application, No. US 63/778,610, by CHIU, et al., titled “SYSTEM AND METHOD OF OFFSET INSPECTION,” filed on Mar. 27, 2025, which is hereby incorporated by reference in their entirety.

### BACKGROUND OF THE INVENTION

### Technical Field

The present invention relates to a system and method of offset inspection. More particularly, the present invention relates to system and method of offset inspection for use in conjunction with a substrate carrier.

### Description of Related Art

In the semiconductor industry, various semiconductor substrates, such as wafers, reticles, or other thin plate substrates, are used in the manufacturing processes for fabricating semiconductor devices. In order to prevent semiconductor substrates from collision damage or exposure to environmental contamination during transfer between work stations, the semiconductor substrates are known to be accommodated in a substrate carrier.

With continuous advancement of semiconductor technologies and the ongoing trend toward reduced line width, process conditions have become increasingly strict. As a result, higher requirements are imposed on equipment such as machines, work stations, and robotic arms with respect to alignment accuracy and dimensional precision at various stages of the fabrication process. Similarly, in a substrate carrier, the alignment accuracy for the semiconductor substrates and the assembly accuracy of the substrate carrier itself directly affect whether the robotic arms can accurately pick up and place the semiconductor substrates. Therefore, the semiconductor industry has placed increasingly higher demands on the assembly precision of substrate carriers.

In known techniques, before deploying to a commercial production line, a substrate carrier is required to be tested, such that the alignment conditions of the semiconductor substrate and its assembly accuracy can be inspected. The substrate carrier includes several locations that require measurement, yet the conventional inspection methods are performed on a single-point measurement basis. As a result, the conventional inspection methods require repeated single-point measurements, which are time-consuming and inefficient. Moreover, after completion of a first measurement, if adjustment of related components of the substrate carrier is required, a second measurement must be performed afterwards. Such repetitive single-point measurement processes consume a substantial amount of time and adversely affect overall production efficiency.

Therefore, how to efficiently inspect alignment accuracy of semiconductor substrates in a substrate carrier, as well as assembly accuracy of the substrate carrier itself, has become an important technical issue that needs to be solved.

### SUMMARY

In view of the above-mentioned problems, the present invention provides a system and a method of offset inspection. By using multiple inspection points distributed on a common reference plane for point placement, multiple inspection points can be inspected in batch, thereby shortening inspection time and improving the overall inspection efficiency.

According to one aspect of the invention, a system of offset inspection configured to be used in conjunction with a substrate carrier is provided. The substrate carrier is configured to accommodate multiple substrates to be inspected. The system of offset inspection includes multiple inspection elements configured to inspect, in batch, multiple first offset values of the substrates to be inspected, or to inspect, in batch, multiple second offset values of the substrate carrier. Each inspection element has an inspection point, and the inspection points of the inspection elements are distributed on a common reference plane for point placement.

In one embodiment, the substrate carrier includes multiple supporting members sequentially disposed therein. Each inspection element is respectively disposed on a corresponding one of the substrates to be inspected, and when the substrates to be inspected are supported on the supporting members, the inspection elements are configured to inspect, in batch, the first offset values of at least one group of the substrates to be inspected.

In another embodiment, the substrate carrier includes multiple supporting members sequentially disposed therein, and the system of offset inspection further includes multiple end effectors configured to move the substrates to be inspected into the substrate carrier and to have the substrates to be inspected supported on the supporting members. Each inspection element is respectively disposed on a corresponding one of the end effectors, and when the substrates to be inspected are supported on the supporting members, the inspection elements are configured to inspect, in batch, the first offset values of at least one group of the substrates to be inspected.

In a further embodiment, the system of offset inspection further includes an inspection board configured to engage with the substrate carrier. The inspection elements are disposed on the inspection board and are configured to inspect, in batch, the first offset values of at least one group of the substrates to be inspected.

In yet another embodiment, the substrate carrier has multiple inspection locations, and the system of offset inspection further includes an inspection board configured to engage with the substrate carrier. The inspection elements are disposed on the inspection board and are configured to inspect, in batch, the second offset values of at least one group of the inspection locations.

In another embodiment, the inspection points are distributed on the reference plane for point placement in a one-dimensional manner or in a two-dimensional manner.

According to another aspect of the invention, a method of offset inspection configured to be used in conjunction with a substrate carrier is provided. The substrate carrier is configured to accommodate multiple substrates to be inspected. The method of offset inspection includes: the step of inspecting, in batch, by multiple inspection elements, multiple first offset values of the substrates to be inspected or multiple second offset values of the substrate carrier. Each inspection element has an inspection point, and the inspection points of the inspection elements are distributed on a common reference plane for point placement.

In one embodiment, the substrate carrier includes multiple supporting members sequentially disposed therein, and the method of offset inspection further includes: the step of moving, by multiple end effectors, the substrates to be inspected into the substrate carrier and having the substrates to be inspected supported on the supporting members; and the step of inspecting, in batch, by the inspection elements disposed on the substrates to be inspected, the first offset values of at least one group of the substrates to be inspected.

In another embodiment, the substrate carrier includes multiple supporting members sequentially disposed therein, and the method of offset inspection further includes: the step of moving, by multiple end effectors, the substrates to be inspected into the substrate carrier and having the substrates to be inspected supported on the supporting members; and the step of inspecting, in batch, by the inspection elements disposed on the end effectors, the first offset values of at least one group of the substrates to be inspected.

In a further embodiment, the method of offset inspection further includes: the step of engaging an inspection board with the substrate carrier; and the step of inspecting, in batch, by the inspection elements disposed on the inspection board, the first offset values of at least one group of the substrates to be inspected.

In yet another embodiment, the substrate carrier has multiple inspection locations, and the method of offset inspection further includes: the step of engaging an inspection board with the substrate carrier; and the step of inspecting, in batch, by the inspection elements disposed on the inspection board, the second offset values of at least one group of the inspection locations.

The embodiments of the present invention provide the system of offset inspection and the method of offset inspection that use multiple inspection elements, with inspection points thereof distributed on the common reference plane for point placement. In this manner, repetitive single-point measurement operations can be omitted, and multiple offset values can be obtained in a single inspection operation. The disclosed system and method are configured to simultaneously obtain the inspection results of multiple substrates to be inspected, as well as the inspection results of multiple inspection locations of the substrate carrier. As a result, the inspection time can be significantly shortened, and overall inspection efficiency can be improved.

### BRIEF DESCRIPTION OF DRAWINGS

The present invention can be more fully understood by reading the following detailed description of the embodiment, with reference made to the accompanying drawings as follows.

FIG. 1 is a schematic diagram of a system of offset inspection according to one embodiment of the invention.

FIG. 2 is a schematic diagram of the substrate carrier of FIG. 1 and an inspection platform.

FIG. 3 is a schematic diagram of a bottom portion of the substrate carrier of FIG. 1.

FIG. 4 is a schematic diagram showing the substrate to be inspected is not offset.

FIG. 5 is a schematic diagram showing the substrate to be inspected is offset.

FIG. 6 is a schematic diagram of a system of offset inspection according to another embodiment of the invention.

FIG. 7 is a schematic diagram showing the substrate to be inspected is not offset.

FIG. 8 is a schematic diagram showing the substrate to be inspected is offset.

FIG. 9 is a schematic diagram of a system of offset inspection according to yet another embodiment of the present invention.

FIG. 10 is a schematic diagram showing the distribution of the inspection points on the common reference plane for point placement of FIG. 9.

FIG. 11 is a schematic diagram of a system of offset inspection according to still another embodiment of the present invention.

FIG. 12 is a schematic diagram showing the distribution of the inspection points on the common reference plane for point placement of FIG. 11.

FIG. 13 is a flowchart of a method of offset inspection according to one embodiment of the invention.

FIG. 14 is a flowchart of a method of offset inspection according to another embodiment of the invention.

FIG. 15 is a flowchart of a method of offset inspection according to yet another embodiment of the present invention.

FIG. 16 is a flowchart of a method of offset inspection according to still another embodiment of the present invention.

### DETAILED DESCRIPTION

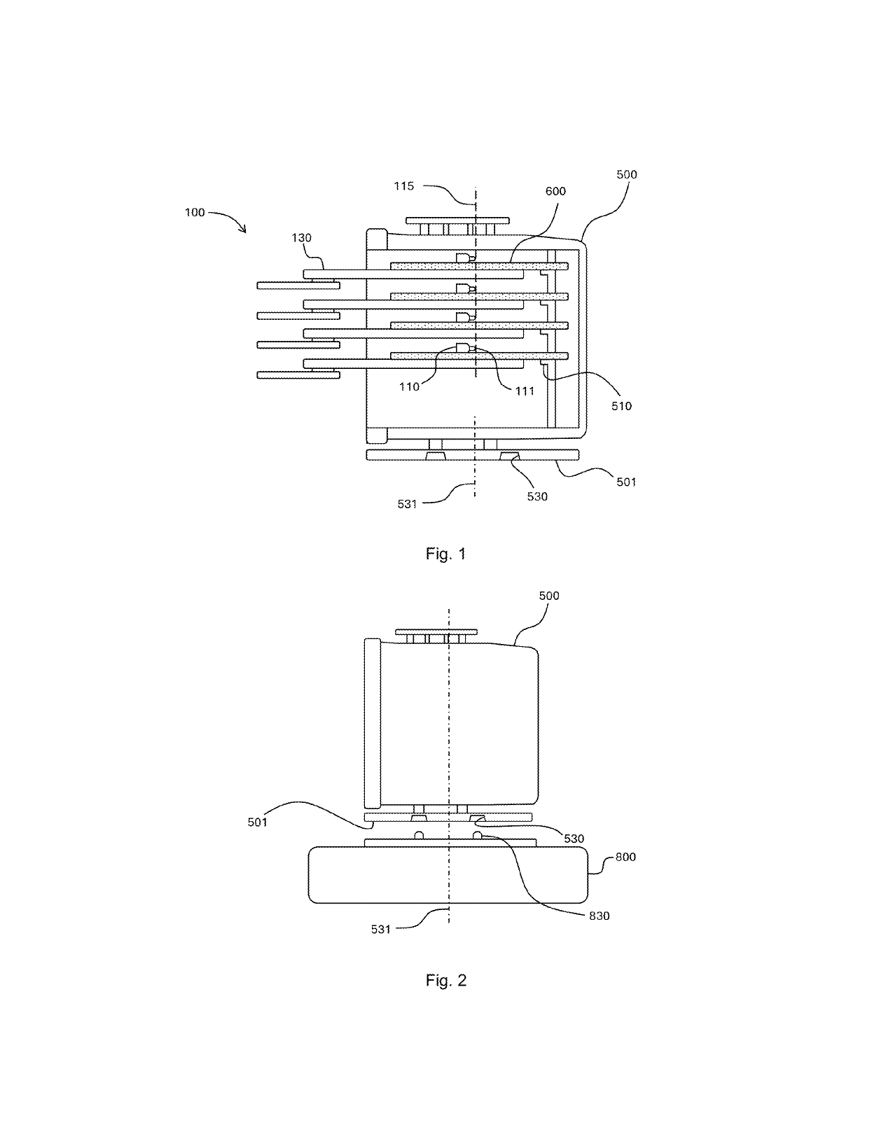

Please refer to FIG. 1, which is a schematic diagram of a system of offset inspection according to one embodiment of the invention. The system of offset inspection 100 of the present embodiment is configured to be used in conjunction with a substrate carrier 500. The substrate carrier 500 is configured to accommodate multiple substrates to be inspected 600. The system of offset inspection 100 includes multiple inspection elements 110 that are configured to inspect, in batch, two or more first offset values of the substrates to be inspected 600. Each inspection element 110 has an inspection point 111, and the inspection points 111 of the inspection elements 110 are distributed on a common reference plane for point placement 115. By using the inspection elements 110, inspection process can be carried out in a batch manner (i.e., multiple inspection points 111 at one time), such that multiple first offset values can be obtained in each inspection. Therefore, a large amount of repetitive single-point inspections may be omitted, thereby shortening the inspection time, improving the overall efficiency.

It should be noted that the substrates to be inspected 600 may be test wafers or test photomasks provided by manufacturers for verifying specifications of actual substrates, or for adjusting and fine-tuning parameters associated with substrate-related fabrication processes. The substrates to be inspected 600 used in the embodiments of the present invention are not limited to wafers or photomasks; any semiconductor substrate requiring alignment and offset inspection in the field of semiconductor fabrication may be used as the substrate to be inspected 600 here. In addition, the substrates to be inspected 600 may be circular, rectangular, or of any other shape suitable for semiconductor fabrication processes.

In this embodiment, the substrate carrier 500 includes multiple supporting members 510 sequentially disposed therein. The supporting members 510 are sequentially and equal-distantly arranged in a vertical direction and are located on the inner side of the substrate carrier 500. The supporting members 510 are configured for respectively supporting the substrates to be inspected 600. The structure and configuration of the supporting members 510 are not limited in the present embodiment, so long as the supporting members 510 can be used to support the substrates to be inspected 600 inside the substrate carrier 500. All similar variations of the supporting members 510 fall within the scope of the present invention.

The system of offset inspection 100 further includes multiple end effectors 130 that are configured to move the substrates to be inspected 600 into the substrate carrier 500 and to have the substrates to be inspected 600 supported on the supporting members 510. In this embodiment, each end effector 130 is used to move one substrate to be inspected 600 into the substrate carrier 500. These end effectors 130 may operate simultaneously to move multiple substrates to be inspected 600 into the substrate carrier 500 at the same time; or alternatively, the end effectors 130 may move the substrates to be inspected 600 into the substrate carrier 500 sequentially. The order of moving the substrates to be inspected 600 into the substrate carrier 500 is not limited here in the present invention.

In the present embodiment, each inspection element 110 is disposed on a corresponding one of the substrates to be inspected 600. When the substrates to be inspected 600 are supported on the supporting members 510, the inspection elements 110 are configured to inspect, in batch, multiple first offset values of at least one group of the substrates to be inspected 600. Each group includes two or more substrates to be inspected 600. When the number of the substrates to be inspected 600 included in each group increases, the number of the groups required to complete the inspection of all substrates to be inspected 600 decreases. Therefore, the overall inspection time and efficiency can be improved.

For example, the system of offset inspection 100 is used with a large substrate carrier 500 whose supporting members 510 constitute twenty-five supporting slots for receiving twenty-five substrates to be inspected 600. In the case that each group includes five substrates to be inspected 600, the inspection elements 110 obtain five first offset values in each inspection. To obtain all twenty-five first offset values of the twenty-five substrates to be inspected 600, the system of offset inspection 100 needs to perform five groups of inspections. In a preferred embodiment, one group includes all twenty-five substrates to be inspected 600, such that the system of offset inspection 100 only needs to perform one group of inspection to obtain all twenty-five first offset values. The number of substrates to be inspected 600 included in each group may be adjusted as needed and is not limited in the present invention.

In this embodiment, each inspection element 110 is disposed on a corresponding one of the substrates to be inspected 600, and the inspection points 111 of the inspection elements 110 are distributed on the same, common reference plane for point placement 115. The common reference plane for point placement 115 may be, for example, a virtual vertical plane, as shown in FIG. 1. The inspection points 111 are equally spaced in the vertical direction. When the substrates to be inspected 600 are placed into the substrate carrier 500, multiple first offset values may be obtained simultaneously by performing inspection via the inspection points 111 disposed on the common reference plane for point placement 115.

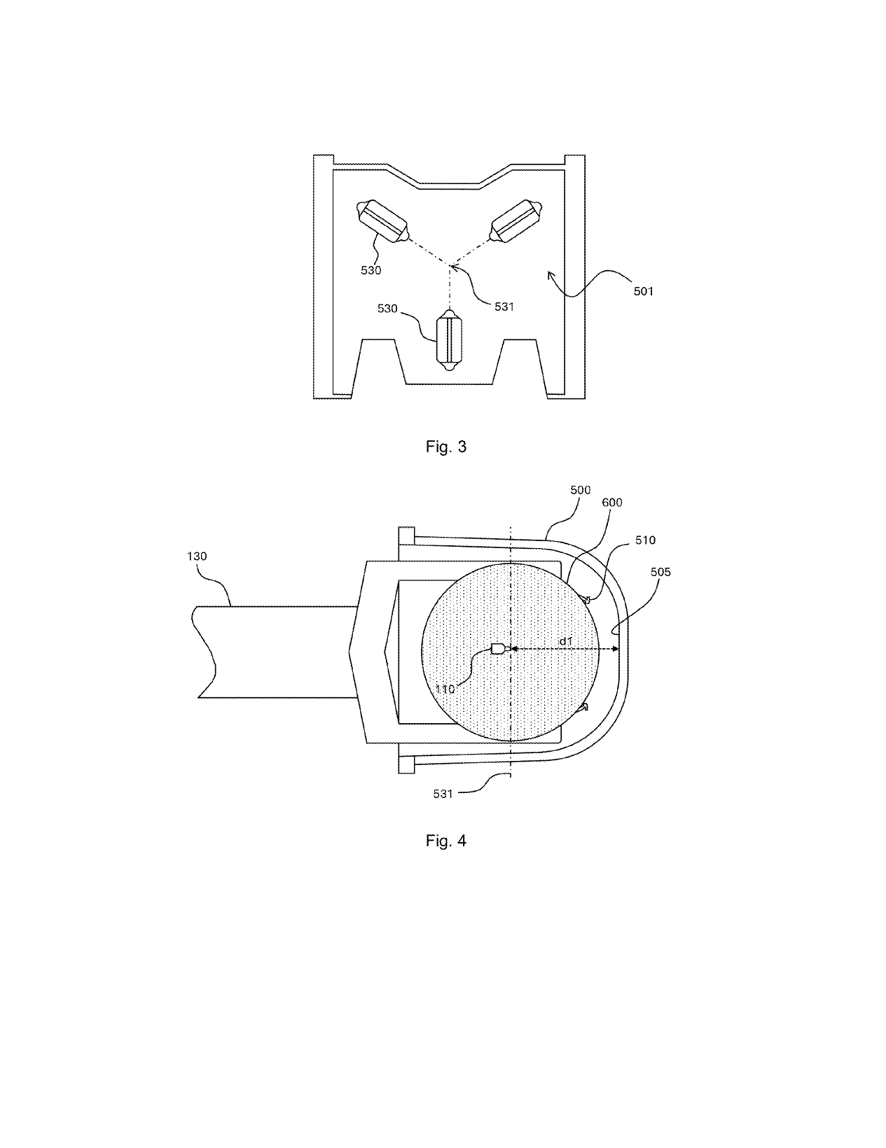

Please refer to FIGS. 1, 2, and 3 at the same time. FIG. 2 is a schematic diagram of the substrate carrier of FIG. 1 and an inspection platform. FIG. 3 is a schematic diagram of a bottom portion of the substrate carrier of FIG. 1. The system of offset inspection 100 of the present embodiment further includes an inspection platform 800 configured to receive and position the substrate carrier 500 thereon. A bottom portion 501 of the substrate carrier 500 is provided with more than one positioning groove members 530. These positioning groove members 530 define a positioning center point 531. In the present embodiment, the first offset values are obtained in accordance with the positioning center point 531. More specifically, each positioning groove member 530 may be a V-shaped kinematic coupling (KC) groove configured to engage with more than one positioning pins 830 on the inspection platform 800 for positioning, thereby fixing the relative position of the substrate carrier 500 on the inspection platform 800. The extended lines of the long axis of the positioning groove members 530 intersect at a single common point, which is defined as the positioning center point 531. In addition, the bottom portion 501 may be, for example, the bottom portion of a base of the substrate carrier 500.

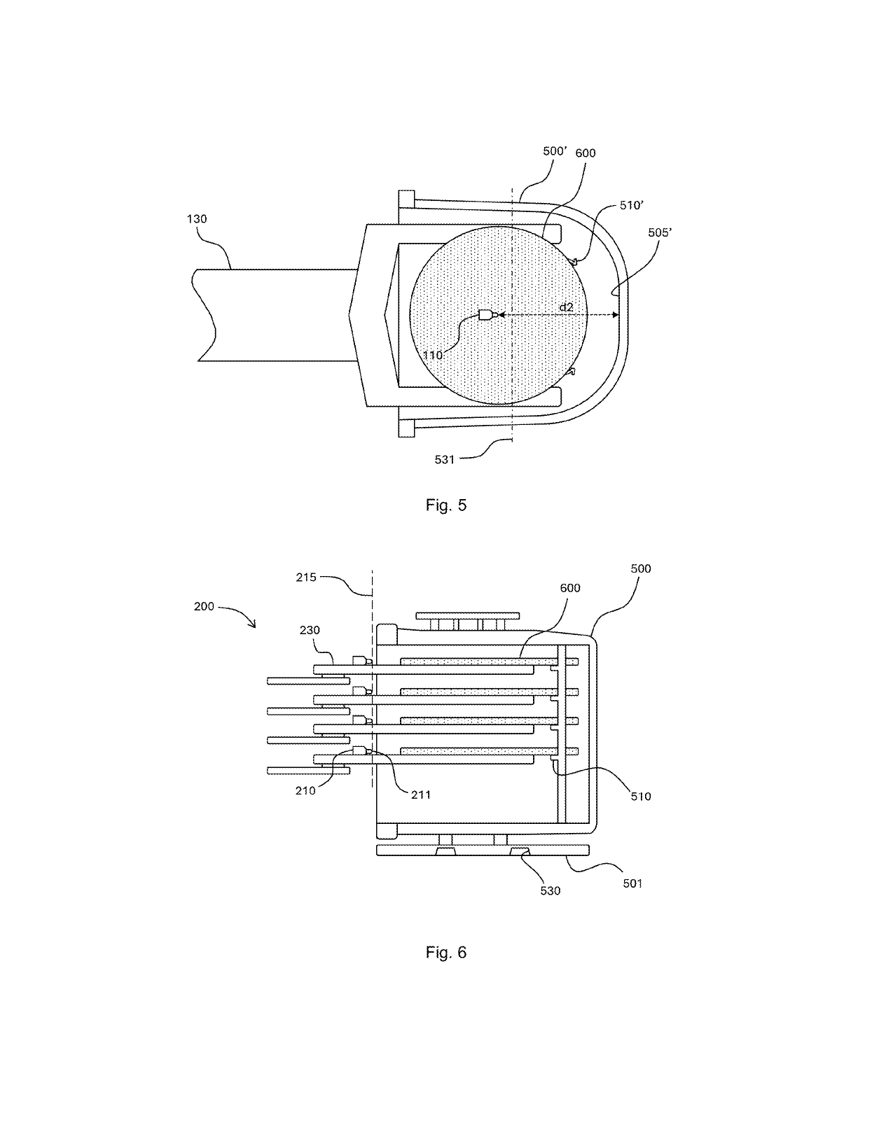

Please refer to FIGS. 4 and 5. FIG. 4 is a schematic diagram showing the substrate to be inspected is not offset. FIG. 5 is a schematic diagram showing the substrate to be inspected is offset. The inspection mechanism of the first offset values according to the present embodiment will be described below. Under a standard condition (or refer to as a normal condition), the components of the substrate carrier 500 are properly assembled and conform to the dimensions and specifications. In one embodiment, each inspection element 110 is configured to inspect a distance from a center of the corresponding substrate to be inspected 600 to an inner wall of the back plate 505 of the substrate carrier 500. Alternatively, each inspection element 110 may be configured to inspect a distance from a center or an edge of the corresponding substrate to be inspected 600 to an inner sidewall of the substrate carrier 500. The inspection locations of the inspection elements 110 are not limited in the embodiments of the invention. In addition, each inspection element 110 may, for example, include an optical distance sensor; however, other types of sensors, such as contact-type sensors or ultrasonic sensors, may also be implemented in the present invention.

As shown in FIG. 4, when the substrate to be inspected 600 is moved by the end effector 130 into the substrate carrier 500 and positioned therein, the substrate to be inspected 600 is supported on the supporting members 510, and the edge of the substrate to be inspected 600 is in contact with the supporting members 510. In the state shown in FIG. 4, the substrate to be inspected 600 is located at the standard position without offset. The center of the substrate to be inspected 600 coincides with the positioning center point 531. The inspection element 110 obtains a reference distance d1 from the center of the substrate to be inspected 600 to the inner wall of the back plate 505.

As shown in FIG. 5, in the case that when the assembly tolerances occur during assembly of the substrate carrier 500’, for example, due to inclination, twisting, or incorrect fixing positions while installing the supporting members 510’, the position of the substrate to be inspected 600 inside the substrate carrier 500’ is affected, thereby resulting in a positional offset. In such a case, the center of the substrate to be inspected 600 does not coincide with the positioning center point 531, and a distance exists therebetween. During the inspection process, when the substrate to be inspected 600 is moved by the end effector 130 into the substrate carrier 500’ and positioned therein, the substrate to be inspected 600 is supported on the supporting members 510’, and the edge of the substrate to be inspected 600 is in contact with the supporting members 510’. In the state shown in FIG. 5, as compared with the standard condition shown in FIG. 4, the substrate to be inspected 600 is offset. The inspection element 110 disposed on the substrate to be inspected 600 obtains an inspection distance d2 from the center of the substrate to be inspected 600 to the inner wall of the back plate 505’. The offset amount of the substrate to be inspected 600 is acquired based on a difference between the inspection distance d2 and the reference distance d1. The acquired offset amount is defined as the first offset value of the substrate to be inspected 600 in the embodiment of the invention.

In the embodiment shown in FIG. 5, although the inspection of a single substrate to be inspected 600 is taken as an example, it is provided merely to clearly show the features of the present invention. During the inspection process, the system of offset inspection 100 in the embodiment of the invention uses two or more inspection elements 110 to inspect, in batch, a group of substrates to be inspected 600, such that multiple first offset values can be obtained in a single inspection operation. In addition, after inspection, when one or more of the first offset values exceed a threshold value, it indicates that assembly tolerances of the substrate carrier 500’ are excessive and fail to satisfy the inspection requirements. In such a case, further adjustment or replacement of one or more components of the substrate carrier 500’ is required.

According to the above-described embodiment of the invention, the system of offset inspection 100 uses multiple inspection elements 110 respectively disposed on the substrates to be inspected 600 to inspect, in batch, multiple first offset values of the substrates to be inspected 600. Therefore, a large amount of repetitive single-point inspection operations are omitted, thereby shortening the inspection time and improving overall efficiency.

Please refer to FIG. 6, which is a schematic diagram of a system of offset inspection according to another embodiment of the invention. The system of offset inspection 200 of the present embodiment is configured to be used in conjunction with a substrate carrier 500, and the substrate carrier 500 is configured to accommodate multiple substrates to be inspected 600. The system of offset inspection 200 includes multiple inspection elements 210 that are configured to inspect, in batch, multiple first offset values of the substrates to be inspected 600. Each inspection element 210 has an inspection point 211, and the inspection points 211 of the inspection elements 210 are distributed on a common reference plane for point placement 215. By using two or more inspection elements 210, the inspection process can be carried out in a batch manner (i.e., multiple inspection points 211 at one time), such that multiple first offset values can be obtained in each inspection operation. In this embodiment, the substrate carrier 500 includes multiple supporting members 510 sequentially disposed therein, and the structure and configuration of the supporting members 510 are not limited in the embodiment of the present invention. The system of offset inspection 200 further includes multiple end effectors 230 that are configured to move the substrates to be inspected 600 into the substrate carrier 500 and to have the substrates to be inspected 600 supported on the supporting members 510.

In the present embodiment, each inspection element 210 is disposed on a corresponding one of the end effectors 230. When the substrates to be inspected 600 are supported on the supporting members 510, the inspection elements 210 are configured to inspect, in batch, multiple first offset values of at least one group of the substrates to be inspected 600. Each group includes two or more substrates to be inspected 600. As the number of substrates to be inspected 600 included in each group increases, the number of groups required to inspect all of the substrates to be inspected 600 decreases, thereby shortening the inspection time and improving overall efficiency. In addition, a bottom portion 501 of the substrate carrier 500 is provided with two or more positioning groove members 530, which may be, for example, V-shaped kinematic coupling grooves configured to engage with multiple positioning pins 830 on the inspection platform 800 (as shown in FIG. 2) for positioning, thereby fixing a relative position of the substrate carrier 500 on the inspection platform 800.

In addition, in the present embodiment, each inspection element 210 is disposed on a corresponding one of the end effectors 230, and the inspection points 211 of the inspection elements 210 are distributed on the common reference plane for point placement 215. The common reference plane for point placement 215 may be, for example, a virtual vertical plane, as shown in FIG. 6. The inspection points 211 are equally spaced in a vertical direction on the common reference plane for point placement 215. Accordingly, when the substrates to be inspected 600 are placed into the substrate carrier 500, multiple first offset values are obtained simultaneously by performing inspections via the inspection points 211 located on the common reference plane for point placement 215.

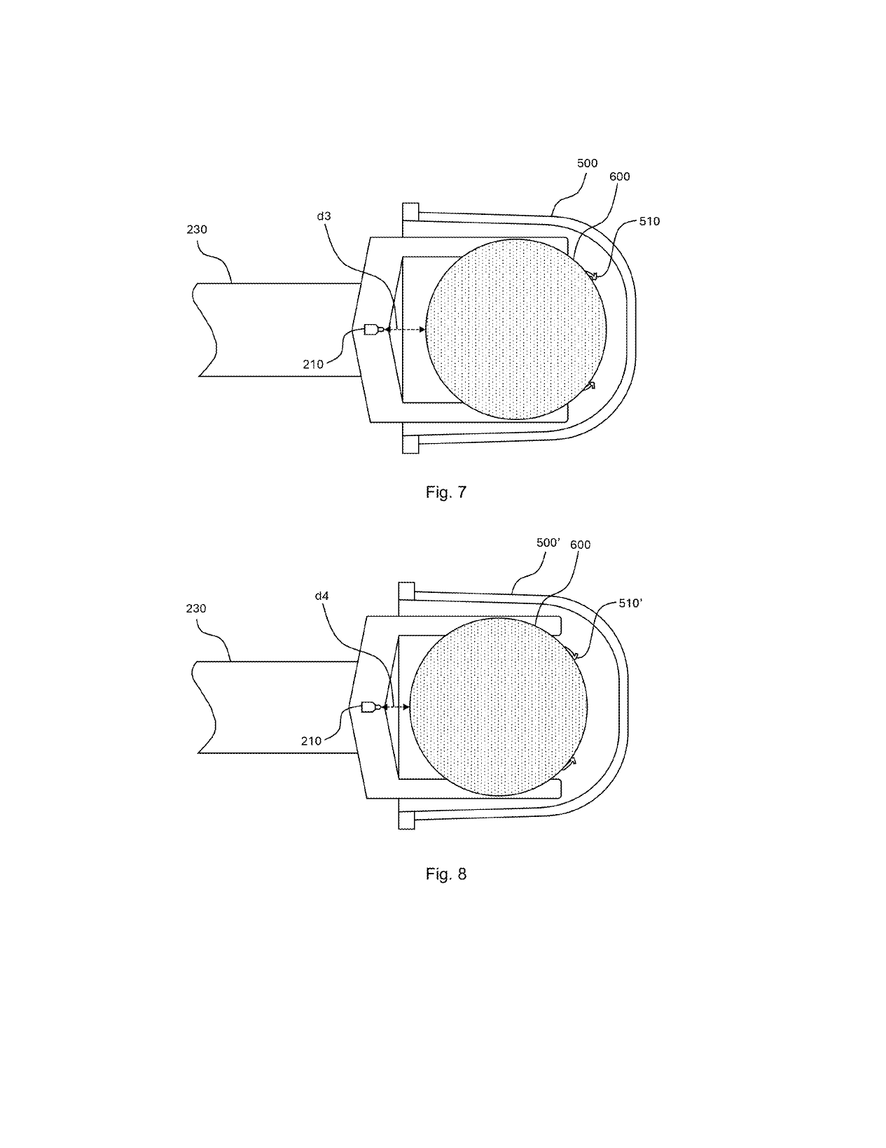

Please refer to FIGS. 7 and 8. FIG. 7 is a schematic diagram showing the substrate to be inspected is not offset. FIG. 8 is a schematic diagram showing the substrate to be inspected is offset. Under a standard (or normal) condition, the components of the substrate carrier 500 are properly assembled and conform to the design dimensions and specifications. In one example, each inspection element 210 is configured to inspect a distance from the end effector 230 to the edge of the substrate to be inspected 600. As shown in FIG. 7, when the substrate to be inspected 600 is moved by the end effector 230 into the substrate carrier 500 and positioned therein, the substrate to be inspected 600 is supported on the supporting members 510, and the edge of the substrate to be inspected 600 is in contact with the supporting members 510. In the state shown in FIG. 7, the substrate to be inspected 600 is located at a standard position without offset, and the inspection element 210 obtains a reference distance d3.

As shown in FIG. 8, when the assembly tolerances occur during assembling the substrate carrier 500’, for example, due to inclination, twisting, or incorrect fixing positions of the supporting members 510’, the position of the substrate to be inspected 600 inside the substrate carrier 500’ is affected, thereby resulting in a positional offset. During the inspection process, when the substrate to be inspected 600 is moved by the end effector 230 into the substrate carrier 500’ and positioned therein, the substrate to be inspected 600 is supported on the supporting members 510’, and the edge of the substrate to be inspected 600 is in contact with the supporting members 510’. As compared with the standard condition shown in FIG. 7, the substrate to be inspected 600 is offset. In such a case, the inspection element 210 disposed on the end effector 230 obtains an inspection distance d4. The inspection element 210 obtains the offset amount of the substrate to be inspected 600 based on a difference between the inspection distance d4 and the reference distance d3. The offset amount is defined as the first offset value in the embodiment of the present invention.

During the inspection process, the system of offset inspection 200 in the embodiment uses two or more inspection elements 210 to inspect, in batch, a group of substrates to be inspected 600, such that multiple first offset values can be obtained in a single inspection operation. When one or more of the first offset values exceed a threshold value, it indicates that assembly tolerances of the substrate carrier 500’ are excessive and fail to satisfy the inspection requirements. In such a case, further adjustment or replacement of one or more components of the substrate carrier 500’ is required.

As described above, the system of offset inspection 200 according to the embodiment of the present invention uses multiple inspection elements 210 disposed on the end effectors 230 to inspect, in batch, multiple first offset values of the substrates to be inspected 600. Accordingly, a large number of repetitive single-point inspection operations are omitted, thereby shortening the inspection time and improving the overall inspection efficiency.

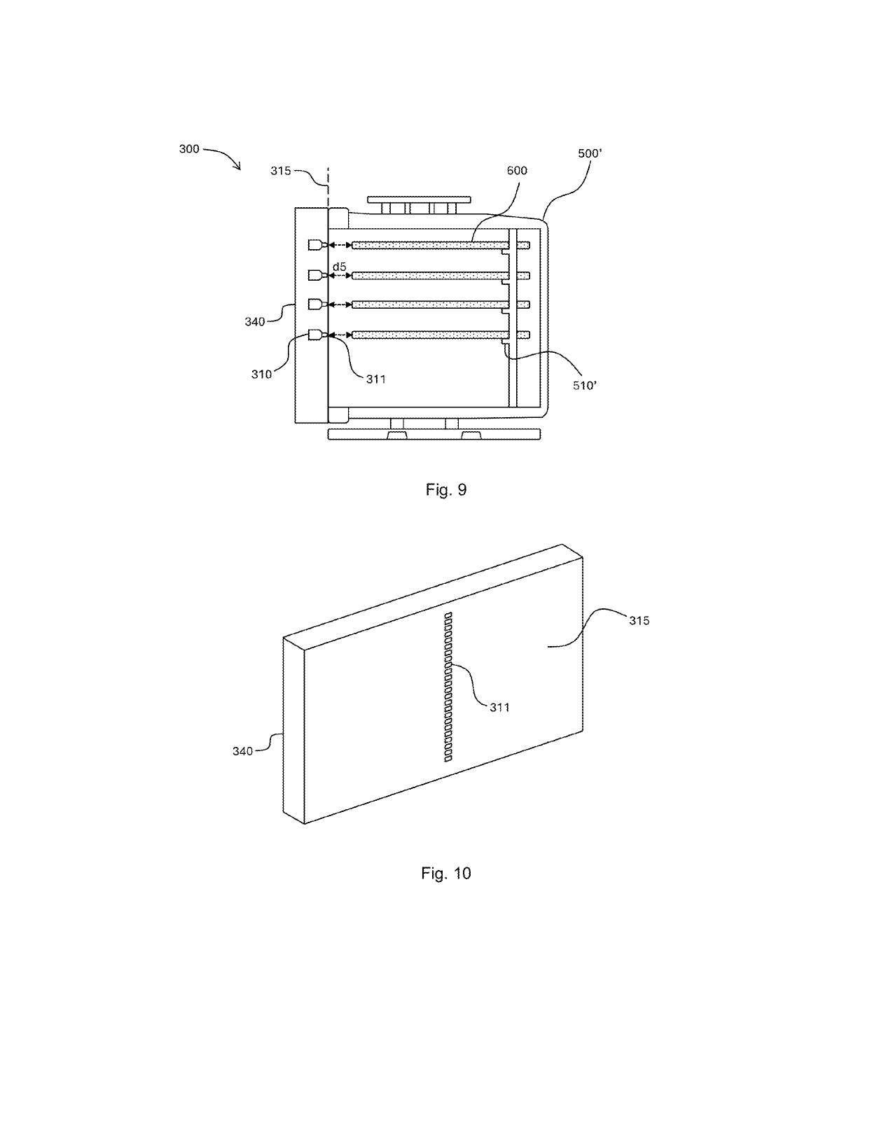

Please refer to FIGS. 9 and 10. FIG. 9 is a schematic diagram of a system of offset inspection according to yet another embodiment of the present invention. FIG. 10 is a schematic diagram showing the distribution of the inspection points on the common reference plane for point placement of FIG. 9. The system of offset inspection 300 of this embodiment is configured to be used in conjunction with a substrate carrier 500’. The substrate carrier 500’ is configured to accommodate multiple substrates to be inspected 600. The system of offset inspection 300 includes multiple inspection elements 310 that are configured to inspect, in batch, multiple first offset values of the substrates to be inspected 600. Each inspection element 310 has an inspection point 311, and the inspection points 311 of the inspection elements 310 are distributed on the common reference plane for point placement 315. By using two or more inspection elements 310, the inspection process can be carried out in a batch manner (i.e., multiple inspection points 311 at one time), such that multiple first offset values are obtained in each inspection operation. As a result, a large number of repetitive single-point inspection operations are omitted, thereby shortening the inspection time and improving the overall inspection efficiency.

In the present embodiment, the substrate carrier 500’ includes multiple supporting members 510’ sequentially disposed therein for supporting the substrates to be inspected 600. The substrates to be inspected 600 are, for example, moved into the substrate carrier 500’ by multiple end effectors and supported on the supporting members 510’. The system of offset inspection 300 further includes an inspection board 340 that is configured to engage with the substrate carrier 500’. The inspection elements 310 are disposed on the inspection board 340 and are configured to inspect, in batch, multiple first offset values of at least one group of the substrates to be inspected 600. In this embodiment, the inspection board 340 engages with the substrate carrier 500’ at one side having an opening, such that the inspection points 311 of the inspection elements 310 face their corresponding ones of the substrates to be inspected 600. The inspection points 311 are distributed in a one-dimensional manner on the common reference plane for point placement 315. As shown in FIG. 9, the inspection points 311 are sequentially and equally spaced in a vertical direction on the reference plane for point placement 315. Each inspection point 311 corresponds, in height, to one of the substrates to be inspected 600, thereby achieving the measurement of a distance from the inspection point 311 to the edge of the corresponding substrate to be inspected 600. In this embodiment, the reference plane for point placement 315 is a vertical plane on the inspection board 340.

Under a standard (or normal) condition, the components of the substrate carrier 500 (as shown in FIGS. 1 or 6) are properly assembled and conform to the design dimensions and specifications. In such a condition, the substrates to be inspected 600 are located at standard positions without offset, and the inspection elements 310 respectively obtain reference distances. As shown in FIG. 9, in the inspection process, when assembly tolerances occur during assembly of the substrate carrier 500’, for example, due to inclination, twisting, or incorrect fixing positions of the supporting members 510’, the positions of the substrates to be inspected 600 inside the substrate carrier 500’ are affected, such that positional offsets occur. When the substrates to be inspected 600 are moved into the substrate carrier 500’ and positioned therein, the substrates to be inspected 600 are supported on the supporting members 510’, and edges of the substrates to be inspected 600 are in contact with the supporting members 510’. At this state, as compared with the standard condition, the substrates to be inspected 600 are offset, and the inspection elements 310 disposed on the inspection board 340 respectively obtain inspection distances d5. The inspection elements 310 obtain offset amounts of the substrates to be inspected 600 based on a difference between each inspection distance d5 and the reference distance. The offset amounts are defined as the first offset values in the embodiment of the present invention.

During the inspection process, the system of offset inspection 300 uses multiple inspection elements 310 to inspect, in batch, the substrates to be inspected 600, such that multiple first offset values are obtained in a single inspection operation. When one or more of the first offset values exceed a threshold value, it indicates that assembly tolerances of the substrate carrier 500’ are excessive and fail to satisfy the inspection requirements. In such a case, further adjustment or replacement of one or more components of the substrate carrier 500’ is required.

As described above, the system of offset inspection 300 according to the embodiment of the present invention uses multiple inspection elements 310 disposed on the inspection board 340 to inspect, in batch, multiple first offset values of the substrates to be inspected 600. Accordingly, a large number of repetitive single-point inspection operations are omitted, thereby shortening the inspection time and improving the overall inspection efficiency.

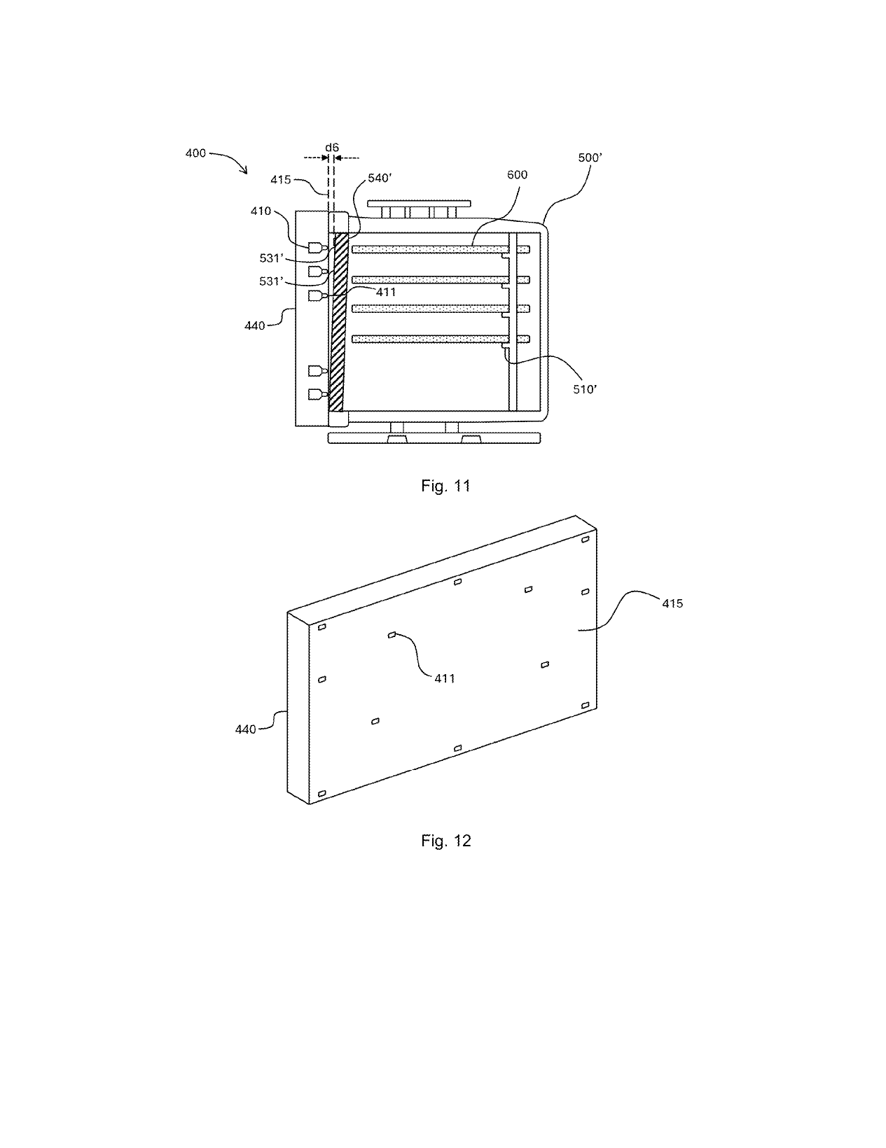

Please refer to FIGS. 11 and 12. FIG. 11 is a schematic diagram of a system of offset inspection according to still another embodiment of the present invention. FIG. 12 is a schematic diagram showing the distribution of the inspection points on the common reference plane for point placement of FIG. 11. The system of offset inspection 400 of this embodiment is configured to be used in conjunction with a substrate carrier 500’. The substrate carrier 500’ is configured to accommodate multiple substrates to be inspected 600. The system of offset inspection 400 includes multiple inspection elements 410 that are configured to inspect, in batch, multiple second offset values of the substrate carrier 500’. Each inspection element 410 has an inspection point 411, and the inspection points 411 of the inspection elements 410 are distributed on the common reference plane for point placement 415. By using two or more of the inspection elements 410, the inspection process can be carried out in a batch manner (i.e., multiple inspection points 411 at one time), such that multiple second offset values can be obtained in each inspection operation. As a result, a large number of repetitive single-point inspection operations are omitted, thereby shortening the inspection time and improving the overall inspection efficiency.

In the present embodiment, the substrate carrier 500’ includes a door 540’ and multiple supporting members 510’ sequentially disposed therein. The supporting members 510’ are configured to support the substrates to be inspected 600. The door 540’ is disposed on one side of the substrate carrier 500’ that has an opening and is configured to enclose the substrate carrier 500’. The substrate carrier 500’ has multiple inspection locations 541’. In the present embodiment, the inspection locations 541’ are located on the door 540’. The substrates to be inspected 600 are, for example, moved into the substrate carrier 500’ by multiple end effectors and supported on the supporting members 510’. The system of offset inspection 400 further includes an inspection board 440 which is configured to engage with the substrate carrier 500’. The inspection elements 410 are disposed on the inspection board 440 and are configured to inspect, in batch, multiple second offset values of at least one group of the inspection locations 541’. In this embodiment, the inspection board 440 is engaged with the substrate carrier 500’ at the side that has the opening, such that the inspection points 411 of the inspection elements 410 face the door 540’, and the inspection points 411 are distributed in a two-dimensional manner on the common reference plane for point placement 415. As shown in FIG. 12, the inspection points 411 are distributed in the two-dimensional manner on the common reference plane for point placement 415 so that they correspond to the respective inspection locations 541’ on the door 540’. In this manner, each inspection element 410 acquires a distance from the inspection point 411 to its corresponding inspection location 541’. In this embodiment, the common reference plane for point placement 415 is a vertical plane of the inspection board 440.

Under a standard (or normal) condition, the components of the substrate carrier 500 (as shown in FIGS. 1 or 6) are properly assembled and conform to the design dimensions and specifications. In such a condition, the substrates to be inspected 600 are located at standard positions without offset, and the inspection elements 410 obtain reference distances. During the inspection process, when assembly tolerances occur during assembly of the substrate carrier 500’, for example, due to inclination, twisting, or incorrect fixing positions while closing the door 540’, the door 540’ may be offset, as shown in FIG. 11. When the position of the door 540’ is offset, the inspection elements 410 disposed on the inspection board 440 obtain inspection distances d6. The inspection elements 410 obtain offset amounts of the door 540’ based on a difference between the inspection distance d6 and the corresponding reference distance, or based on differences among inspection distances d6 corresponding to different inspection locations 541’. Such offset amounts are defined as the second offset values in the present embodiment of the invention.

Although the present embodiment takes the inspection of the second offset values of the door 540’ as an example, the system of offset inspection 400 according to the embodiment of the present invention may also be used to inspect second offset values of other portions of the substrate carrier 500’, such as offset amounts of a door frame. Any configuration that uses multiple inspection elements 410 having inspection points 411 distributed on the common reference plane for point placement 415 to inspect, in batch, multiple second offset values of the substrate carrier 500’ falls within the scope of the present invention.

During the inspection process, the system of offset inspection 400 uses multiple inspection elements 410 to inspect, in batch, a group of inspection locations 541’, such that two or more second offset values are obtained in a single inspection operation. When one or more of the second offset values exceed a threshold value, it indicates that the assembly tolerances of the substrate carrier 500’ are excessive and fail to satisfy the inspection requirements. In such a case, further adjustment or replacement of one or more components of the substrate carrier 500’ is required.

As described above, the system of offset inspection 400 according to the embodiment of the present invention uses multiple inspection elements 410 disposed on the inspection board 440 to inspect, in batch, multiple second offset values of the inspection locations 541’. Accordingly, a large number of repetitive single-point inspection operations are omitted, thereby shortening the inspection time and improving the overall inspection efficiency.

Now the detailed description elaborates a method of offset inspection according to embodiments of the present invention. The method of offset inspection may be performed by the system of offset inspection 100, 200, 300, and 400 described in the foregoing embodiments (as shown in FIGS. 1, 6, 9, and 11). Detailed technical features of the system of offset inspection 100, 200, 300, and 400 will not be repeated herein.

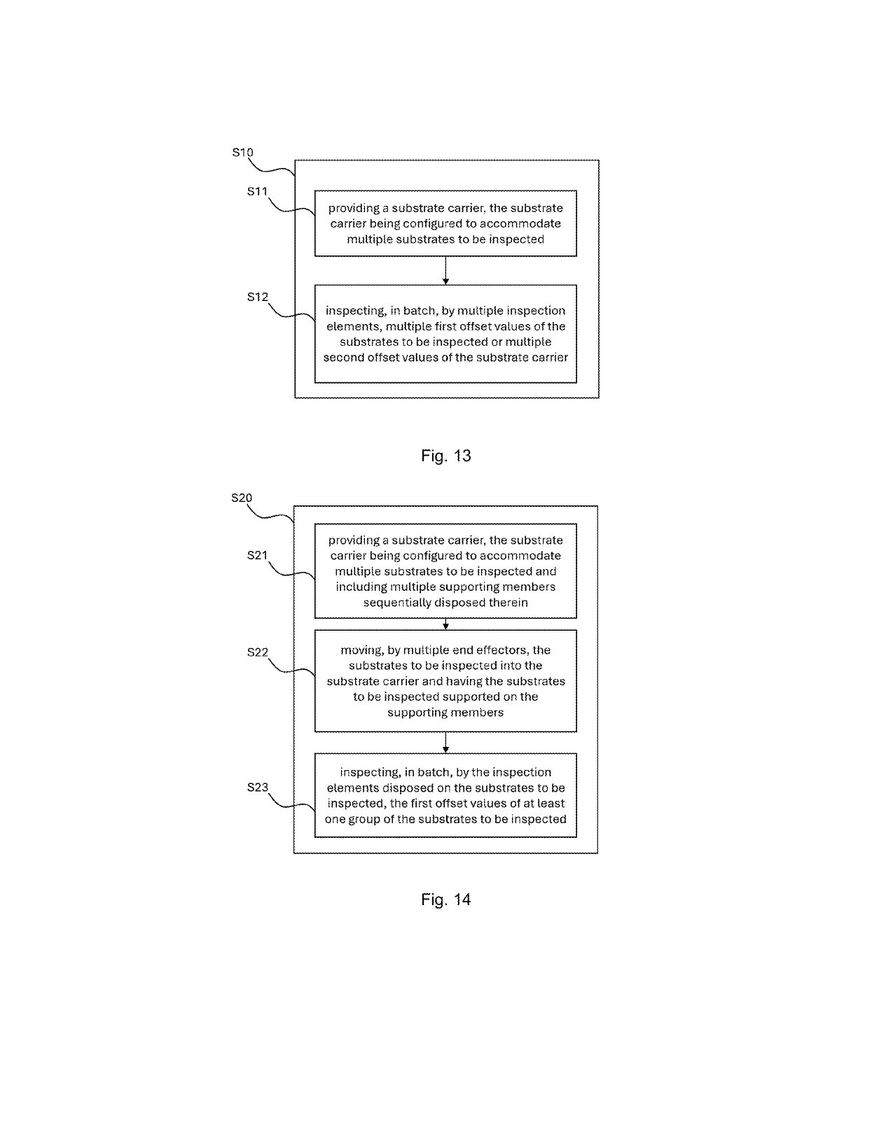

Please refer to FIG. 13, which is a flowchart of a method of offset inspection according to one embodiment of the invention. The method of offset inspection S10 of this embodiment is configured to be used in conjunction with a substrate carrier. In practical implementation of the method of offset inspection S10, step S11 may be performed first to provide a substrate carrier. The substrate carrier is configured to accommodate multiple substrates to be inspected. Subsequently, as shown in step S12, multiple inspection elements are used to inspect, in batch, multiple first offset values of the substrates to be inspected or multiple second offset values of the substrate carrier. Each inspection element has an inspection point, and the inspection points are distributed on a common reference plane for point placement. By using two or more of the inspection elements, the inspection may be carried out in a batch manner (i.e., multiple inspection points at one time), such that multiple first offset values or second offset values can be obtained in each inspection operation. Accordingly, a large number of repetitive single-point inspection operations may be omitted, thereby shortening the inspection time and improving the overall inspection efficiency.

Please refer to FIG. 14, which is a flowchart of a method of offset inspection according to another embodiment of the invention. The method of offset inspection S20 of this embodiment is configured to be used in conjunction with a substrate carrier. In practical implementation of the method of offset inspection S20, step S21 may be performed first to provide a substrate carrier. The substrate carrier is configured to accommodate multiple substrates to be inspected and includes multiple supporting members sequentially disposed therein. In step S22, multiple end effectors are used to move the substrates to be inspected into the substrate carrier and to have the substrates to be inspected supported on the supporting members. Subsequently, as shown in step S23, multiple inspection elements are used to inspect, in batch, multiple first offset values of at least one group of the substrates to be inspected. More specifically, in one embodiment, the inspection elements are disposed on the substrates to be inspected; in another embodiment, the inspection elements are disposed on the end effectors.

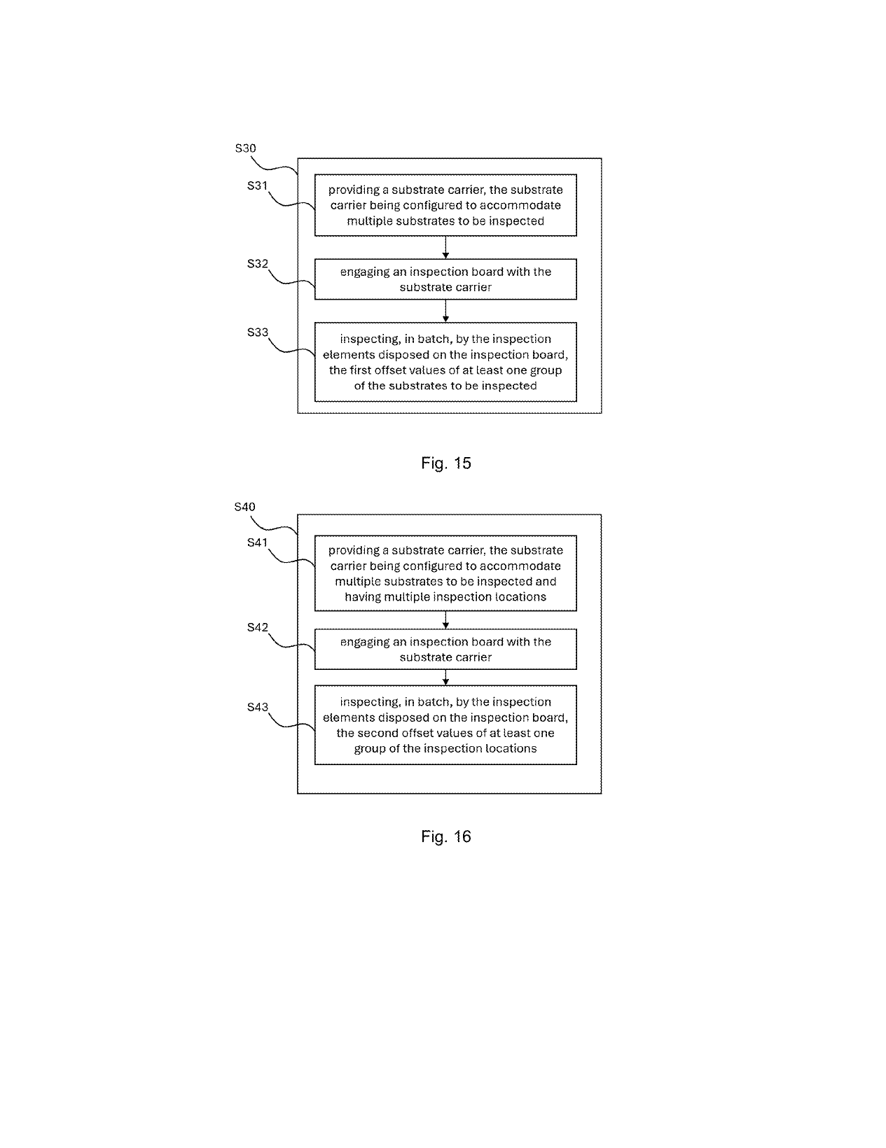

Please refer to FIG. 15, which is a flowchart of a method of offset inspection according to yet another embodiment of the present invention. The method of offset inspection S30 of this embodiment is configured to be used in conjunction with a substrate carrier. In practical implementation of the method of offset inspection S30, step S31 may be performed first to provide the substrate carrier. The substrate carrier is configured to accommodate multiple substrates to be inspected. In step S32, an inspection board is engaged with the substrate carrier. Subsequently, as shown in step S33, multiple inspection elements disposed on the inspection board are used to inspect, in batch, multiple first offset values of at least one group of the substrates to be inspected.

Please refer to FIG. 16, which is a flowchart of a method of offset inspection according to still another embodiment of the present invention. The method of offset inspection S40 of this embodiment is configured to be used in conjunction with a substrate carrier. In practical implementation of the method of offset inspection S40, step S41 may be performed first to provide the substrate carrier. The substrate carrier is configured to accommodate multiple substrates to be inspected and has multiple inspection locations. In step S42, an inspection board is engaged with the substrate carrier. Subsequently, as shown in step S43, multiple inspection elements disposed on the inspection board are used to inspect, in batch, multiple second offset values of at least one group of the inspection locations.

The embodiments of the invention provide a system and method of offset inspection which use multiple inspection elements to inspect, in batch, multiple first offset values of the substrates to be inspected or multiple second offset values of the substrate carrier. Multiple first offset values or multiple second offset values can be obtained in a single inspection operation, hence omitting repetitive single-point inspection operations. The inspection time is shortened, and the overall inspection efficiency is improved.

Although the present invention has been disclosed with a number of embodiments as above, they are not intended to limit the present invention. Any person skilled in the art can make various modifications and refinements without departing from the spirit and scope of the present invention. Therefore, the protection scope of the present invention shall be defined by the scope of the appended claims.

What is claimed is:

1. A system of offset inspection configured to be used in conjunction with a substrate carrier, the substrate carrier being configured to accommodate a plurality of substrates to be inspected, the system of offset inspection comprising:
a plurality of inspection elements configured to inspect, in batch, a plurality of first offset values of the substrates to be inspected or a plurality of second offset values of the substrate carrier;
wherein each inspection element has an inspection point, and the inspection points of the inspection elements are distributed on a common reference plane for point placement.

2. The system of offset inspection according to claim 1, wherein the substrate carrier comprises a plurality of supporting members sequentially disposed therein;
wherein each inspection element is respectively disposed on a corresponding one of the substrates to be inspected, and when the substrates to be inspected are supported on the supporting members, the inspection elements are configured to inspect, in batch, the first offset values of at least one group of the substrates to be inspected.

3. The system of offset inspection according to claim 1, wherein the substrate carrier comprises a plurality of supporting members sequentially disposed therein, and the system of offset inspection further comprises:
a plurality of end effectors configured to move the substrates to be inspected into the substrate carrier and to have the substrates to be inspected supported on the supporting members;
wherein each inspection element is respectively disposed on a corresponding one of the end effectors, and when the substrates to be inspected are supported on the supporting members, the inspection elements are configured to inspect, in batch, the first offset values of at least one group of the substrates to be inspected.

4. The system of offset inspection according to claim 1, further comprising:
an inspection board configured to engage with the substrate carrier;
wherein the inspection elements are disposed on the inspection board and are configured to inspect, in batch, the first offset values of at least one group of the substrates to be inspected.

5. The system of offset inspection according to claim 1, wherein the substrate carrier has a plurality of inspection locations, and the system of offset inspection further comprises:
an inspection board configured to engage with the substrate carrier;
wherein the inspection elements are disposed on the inspection board and are configured to inspect, in batch, the second offset values of at least one group of the inspection locations.

6. The system of offset inspection according to claim 1, wherein the inspection points are distributed on the reference plane for point placement in a one-dimensional manner or in a two-dimensional manner.

7. A method of offset inspection configured to be used in conjunction with a substrate carrier, the substrate carrier being configured to accommodate a plurality of substrates to be inspected, the method of offset inspection comprising:
inspecting, in batch, by a plurality of inspection elements, a plurality of first offset values of the substrates to be inspected or a plurality of second offset values of the substrate carrier;
wherein each inspection element has an inspection point, and the inspection points of the inspection elements are distributed on a common reference plane for point placement.

8. The method of offset inspection according to claim 7, wherein the substrate carrier comprises a plurality of supporting members sequentially disposed therein, the method of offset inspection further comprising:
moving, by a plurality of end effectors, the substrates to be inspected into the substrate carrier and having the substrates to be inspected supported on the supporting members; and
inspecting, in batch, by the inspection elements disposed on the substrates to be inspected, the first offset values of at least one group of the substrates to be inspected.

9. The method of offset inspection according to claim 7, wherein the substrate carrier comprises a plurality of supporting members sequentially disposed therein, the method of offset inspection further comprising:
moving, by a plurality of end effectors, the substrates to be inspected into the substrate carrier and having the substrates to be inspected supported on the supporting members; and
inspecting, in batch, by the inspection elements disposed on the end effectors, the first offset values of at least one group of the substrates to be inspected.

10. The method of offset inspection according to claim 7, further comprising:
engaging an inspection board with the substrate carrier; and
inspecting, in batch, by the inspection elements disposed on the inspection board, the first offset values of at least one group of the substrates to be inspected.

11. The method of offset inspection according to claim 7, wherein the substrate carrier has a plurality of inspection locations, and the method of offset inspection further comprises:
engaging an inspection board with the substrate carrier; and
inspecting, in batch, by the inspection elements disposed on the inspection board, the second offset values of at least one group of the inspection locations.
